(19) United States
(12) Patent Application Publication
(10) Pub. No.: US 2026/0018415 A1
(43) Pub. Date: Jan. 15, 2026

(54) SUBSTRATE PROCESSING METHOD, METHOD OF MANUFACTURING SEMICONDUCTOR DEVICE, RECORDING MEDIUM AND SUBSTRATE PROCESSING APPARATUS

(71) Applicant: KOKUSAI ELECTRIC CORPORATION, Tokyo (JP)

(72) Inventor: Yuki YOSHIMOTO, Toyama (JP)

(73) Assignee: KOKUSAI ELECTRIC CORPORATION, Tokyo (JP)

(21) Appl. No.: 19/332,569

(22) Filed: Sep. 18, 2025

Related U.S. Application Data
(63) Continuation of application No. PCT/JP2023/011163, filed on Mar. 22, 2023.

(51) Int. Cl. H01L 21/02; C23C 16/56; C30B 28/02; C30B 29/06; C30B 29/52

(52) U.S. Cl. CPC H01L 21/0262; C23C 16/56; C30B 28/02; C30B 29/06; C30B 29/52; H01L 21/02381; H01L 21/02488; H01L 21/02513; H01L 21/02532

(57) ABSTRACT

There are provided (a) heat-treating a substrate including a film containing a group 14 element at a first temperature; (b) heat-treating the substrate at a second temperature higher than the first temperature; and (c) exposing the substrate to a treatment agent containing at least one of O and H after performing (a) and before performing (b).

### CROSS-REFERENCE TO RELATED APPLICATION

This application is a Bypass Continuation Application of PCT International Application No. PCT/JP2023/011163, filed on Mar. 22, 2023, the entire contents of which are incorporated herein by reference.

### BACKGROUND

### Field

The present disclosure relates to a substrate processing method, a method of manufacturing a semiconductor device, a recording medium and a substrate processing apparatus.

### Description of the Related Art

As one step of the manufacturing step of the semiconductor device, a step of forming a film containing a group 14 element such as silicon (Si) or germanium (Ge) on a substrate may be performed.

### SUMMARY

The present disclosure provides a technique capable of improving characteristics of a film containing a group 14 element formed on a substrate.

According to an aspect of the present disclosure, there is provided a technique that includes
(a) heat-treating a substrate including a film containing a group 14 element at a first temperature;
(b) heat-treating the substrate at a second temperature higher than the first temperature; and
(c) exposing the substrate to a treatment agent containing at least one of O and H after performing (a) and before performing (b).

### BRIEF DESCRIPTION OF THE DRAWINGS

FIG. 1 is a schematic configuration view of a vertical processing furnace of a substrate processing apparatus suitably used in an aspect of the present disclosure, and is a view illustrating a longitudinal cross-sectional view of a processing furnace 202 portion.

FIG. 2 is a schematic configuration view of the vertical processing furnace of the substrate processing apparatus suitably used in an aspect of the present disclosure, and is a view illustrating a cross-sectional view of the processing furnace 202 portion taken along line A-A of FIG. 1.

FIG. 3 is a schematic configuration view of a controller 121 of the substrate processing apparatus suitably used in an aspect of the present disclosure, and is a diagram illustrating a block diagram of a control system of the controller 121.

FIG. 4 is a diagram illustrating a substrate processing sequence in an aspect of the present disclosure.

FIG. 5 is a diagram illustrating a substrate processing sequence in another aspect of the present disclosure.

FIG. 6A is an enlarged cross-sectional view of a surface of a substrate in an aspect of the present disclosure in which a film containing a group 14 element is formed. FIG. 6B is an enlarged cross-sectional view of a surface of a substrate in another aspect of the present disclosure in which a film containing a group 14 element is formed. FIG. 6C is an enlarged cross-sectional view of a surface of a substrate in another aspect of the present disclosure in which a film containing a group 14 element is formed. FIG. 6D is an enlarged cross-sectional view of a surface of a substrate in another aspect of the present disclosure in which a film containing a group 14 element is formed.

### DETAILED DESCRIPTION

### One Aspect of the Present Disclosure

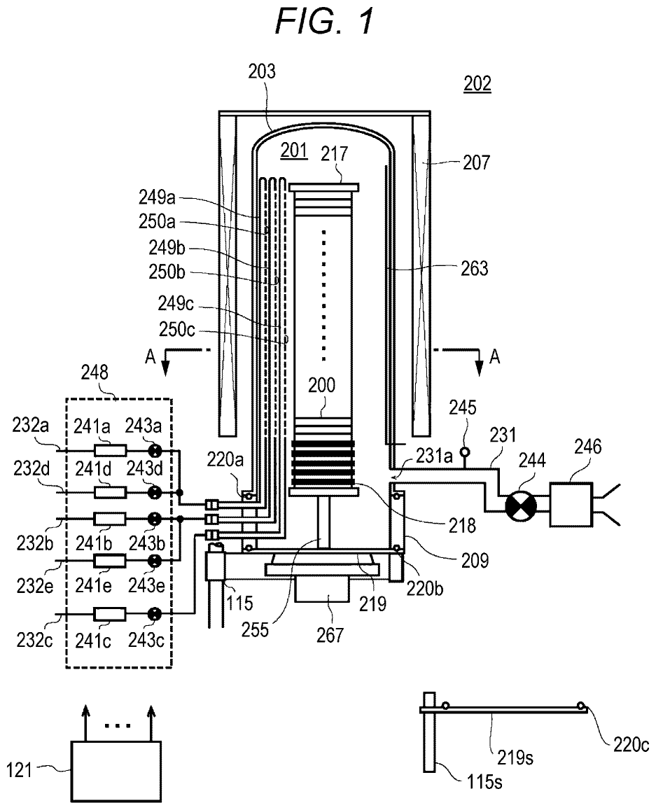

An aspect of the present disclosure will be described later mainly with reference to FIGS. 1 to 4 and 6A. The drawings used in the following description are all schematic, and dimensional relationships of respective elements, ratios of respective elements, and the like illustrated in the drawings do not necessarily coincide with actual ones. In addition, dimensional relationships of the respective elements, ratios of the respective elements, and the like do not necessarily coincide among the plurality of drawings.

### (1) Configuration of Substrate Processing Apparatus

As illustrated in FIG. 1, a processing furnace 202 of a substrate processing apparatus includes a heater 207 serving as a temperature regulator (heater). The heater 207 has a cylindrical shape and is supported by a holding plate to be vertically installed. The heater 207 also functions as an activator (exciter) that thermally activates (excites) a gas.

Inside the heater 207, a reaction tube 203 is arranged concentrically with the heater 207. The reaction tube 203 is composed of, for example, a heat-resistant material such as quartz (SiO₂) or silicon carbide (SiC), and is formed into a cylindrical shape with an upper end closed and a lower end opened. A manifold 209 is arranged below the reaction tube 203 concentrically with the reaction tube 203. The manifold 209 is composed of a metal material such as stainless steel (SUS), for example, into a cylindrical shape with an upper end and a lower end opened. An upper end portion of the manifold 209 engages with a lower end portion of the reaction tube 203 and is configured to support the reaction tube 203. An O-ring 220a serving as a seal is provided between the manifold 209 and the reaction tube 203. The reaction tube 203 is vertically installed similarly to the heater 207. A processing container (reaction container) is configured mainly by the reaction tube 203 and the manifold 209. A process chamber 201 is formed in a cylinder hollow portion of the processing container. The process chamber 201 is configured to be able to accommodate a wafer 200 serving as a substrate. The wafer 200 is processed in the process chamber 201.

In the process chamber 201, nozzles 249a to 249c serving as first to third suppliers, respectively, are provided so as to penetrate a side wall of the manifold 209. The nozzles 249a to 249c are also referred to as first to third nozzles, respectively. The nozzles 249a to 249c are each composed of, for example, a heat-resistant material such as quartz or SiC. Gas supply pipes 232a to 232c are connected to the nozzles 249a to 249c, respectively. The nozzles 249a to 249c are nozzles different from one another, and the nozzles 249a and 249c are provided adjacent to the nozzle 249b.

The gas supply pipes 232a to 232c are provided with mass flow controllers (MFCs) 241a to 241c serving as flow rate controllers (flow rate controllers), and valves 243a to 243c serving as opening/closing valves, respectively, in this order from an upstream side of a gas flow. A gas supply pipe 232d is connected to a downstream side of the valve 243a of the gas supply pipe 232a. A gas supply pipe 232e is connected to a downstream side of the valve 243b of the gas supply pipe 232b. In the gas supply pipes 232d and 232e, MFCs 241d and 241e and valves 243d and 243e are provided, respectively, in this order from an upstream side of a gas flow. The gas supply pipes 232a to 232e are composed of, for example, a metal material such as SUS.

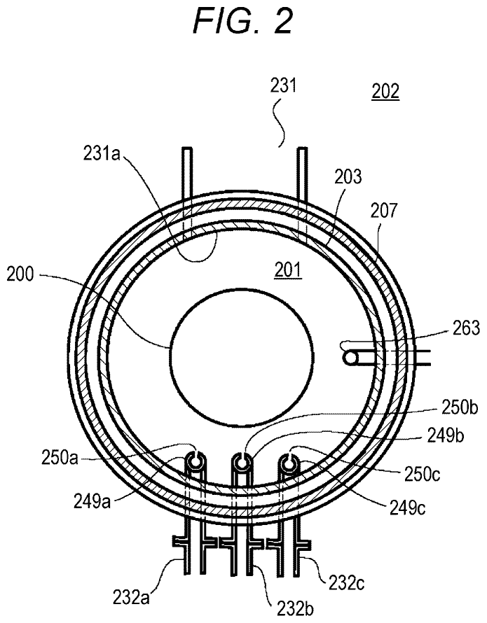

As illustrated in FIG. 2, the nozzles 249a to 249c are provided in an annular space in a plan view between an inner wall of the reaction tube 203 and the wafer 200 so as to extend upward in an arrangement direction of the wafers 200 along the inner wall of the reaction tube 203 from a lower portion to an upper portion. That is, the nozzles 249a to 249c are provided along a wafer arrangement region, in a region horizontally surrounding the wafer arrangement region lateral to the wafer arrangement region in which the wafers 200 are arranged. In a plan view, the nozzle 249b is arranged so as to be opposed to an exhaust port 231a to be described later on a straight line across the center of the wafer 200 in the process chamber 201. The nozzles 249a and 249c are arranged so as to interpose a straight line L passing through the nozzle 249b and the center of the exhaust port 231a from both sides along the inner wall of the reaction tube 203 (outer peripheral portion of the wafer 200). The straight line L is also a straight line passing through the nozzle 249b and the center of the wafer 200. That is, it can also be said that the nozzle 249c is provided on a side opposite to the nozzle 249a across the straight line L. The nozzles 249a and 249c are arranged in line symmetry with the straight line L as a symmetry axis. On side surfaces of the nozzles 249a to 249c, gas supply holes 250a to 250c through which a gas is supplied are formed, respectively. The gas supply holes 250a to 250c are each opened so as to be opposed to (face) the exhaust port 231a in a plan view, and can supply the gas toward the wafer 200. A plurality of gas supply holes 250a to 250c is provided from the lower portion to the upper portion of the reaction tube 203.

A substance containing oxygen (O) and hydrogen (H) is supplied as a treatment agent from the gas supply pipe 232a into the process chamber 201 via the MFC 241a, the valve 243a, and the nozzle 249a.

A substance containing oxygen (O) (a substance composed of O alone and containing no H) is supplied as a treatment agent from the gas supply pipe 232b into the process chamber 201 via the MFC 241b, the valve 243b, and the nozzle 249b.

An inert gas is supplied from the gas supply pipes 232c to 232e into the process chamber 201 via the MFCs 241c to 241e, the valves 243c to 243e, the gas supply pipes 232a to 232c, and the nozzles 249a to 249c, respectively. The inert gas acts as a purge gas, a carrier gas, a diluent gas and the like.

Mainly, the gas supply pipes 232a and 232b, the MFCs 241a and 241b, and the valves 243a and 243b constitute a treatment agent supply system containing at least one of oxygen (O) and hydrogen (H). Mainly, the gas supply pipes 232c to 232e, the MFCs 241c to 241e, and the valves 243c to 243e constitute an inert gas supply system.

Any or all supply systems of the various types of supply systems described above may be configured as an integrated supply system 248 including the valves 243a to 243e and the MFCs 241a to 241e integrated together. The integrated supply system 248 is connected to each of the gas supply pipes 232a to 232e such that the controller 121 to be described later controls the operation of supplying various types of substance (various types of gas) into the gas supply pipes 232a to 232e, namely, the operations of the valves 243a to 243e that open/close and the operations of the MFCs 241a to 241e for regulation in flow rate. The integrated supply system 248 is provided as a single integrated unit or a splittable integrated unit and can be attached to/detached from the gas supply pipes 232a to 232e on an integrated unit basis.

Thus, maintenance, replacement, or addition can be performed to the integrated supply system 248 on an integrated unit basis.

The exhaust port 231a from which an atmosphere inside the process chamber 201 is discharged is formed in a lower portion of a side wall of the reaction tube 203. As illustrated in FIG. 2, the exhaust port 231a is provided at a position opposed to (facing) the nozzles 249a to 249c (gas supply holes 250a to 250c) across the wafer 200 in a plan view. The exhaust port 231a may be provided along the side wall of the reaction tube 203 from the lower portion toward the upper portion, that is, along the wafer arrangement region. An exhaust pipe 231 is connected to the exhaust port 231a. A vacuum pump 246 serving as a vacuum-exhauster is connected to the exhaust pipe 231 via a pressure sensor 245 serving as a pressure detector (pressure detector) that detects a pressure in the process chamber 201 and an auto pressure controller (APC) valve 244 serving as a pressure regulator (pressure regulator). The APC valve 244 is configured to be able to perform vacuum exhaust and stop the vacuum exhaust inside the process chamber 201 by opening and closing the valve in a state where the vacuum pump 246 is operated, and to be able to regulate a pressure in the process chamber 201 by regulating the degree of valve opening on the basis of pressure information detected by the pressure sensor 245 in a state where the vacuum pump 246 is operated. An exhaust system is composed mainly of the exhaust pipe 231, the APC valve 244, and the pressure sensor 245. The vacuum pump 246 may be included in the exhaust system.

Below the manifold 209, a seal cap 219 is provided serving as a furnace opening lid capable of airtightly closing a lower end opening of the manifold 209. The seal cap 219 is composed of, for example, a metal material such as SUS into a disk shape. An O-ring 220b serving as a seal that abuts the lower end of the manifold 209 is provided on an upper surface of the seal cap 219. A rotator 267 that rotates a boat 217 to be described later is arranged below the seal cap 219. A rotating shaft 255 of the rotator 267 penetrates the seal cap 219 and is connected to the boat 217. The rotator 267 is configured to rotate the boat 217, thereby rotating the wafer 200. The seal cap 219 is configured to be lifted up and down in a vertical direction by a boat elevator 115 serving as a lifter arranged outside the reaction tube 203. The boat elevator 115 is configured as a transferrer (transferrer) that lifts the seal cap 219 up and down, thereby loading/unloading (transferring) the wafer 200 into/from the process chamber 201.

Below the manifold 209, a shutter 219s serving as a furnace opening lid capable of airtightly closing the lower end opening of the manifold 209 in a state where the seal cap 219 is lowered and the boat 217 is unloaded from the inside of the process chamber 201 is provided. The shutter 219s is composed of, for example, a metal material such as SUS into a disk shape. An O-ring 220c serving as a seal that abuts the lower end of the manifold 209 is provided on an upper surface of the shutter 219s. An opening/closing operation (lifting operation, rotating operation and the like) of the shutter 219s is controlled by a shutter opener/closer 115s.

The boat 217 serving as a substrate support is configured to support a plurality of, for example, 25 to 200 wafers 200 in multiple stages, that is, to arrange the wafers 200 at intervals, while the wafers 200 are aligned in the vertical direction in a horizontal posture and in a state where the centers thereof are aligned with one another. The boat 217 is composed of, for example, a heat-resistant material such as quartz and SiC. Heat insulating plates 218 each composed of a heat-resistant material, for example, such as quartz or SiC are supported in multiple stages in a lower portion of the boat 217.

A temperature sensor 263 serving as a temperature detector is provided in the reaction tube 203. By regulating the degree of energization to the heater 207 on the basis of temperature information detected by the temperature sensor 263, the temperature in the process chamber 201 has a desired temperature distribution. The temperature sensor 263 is provided along the inner wall of the reaction tube 203.

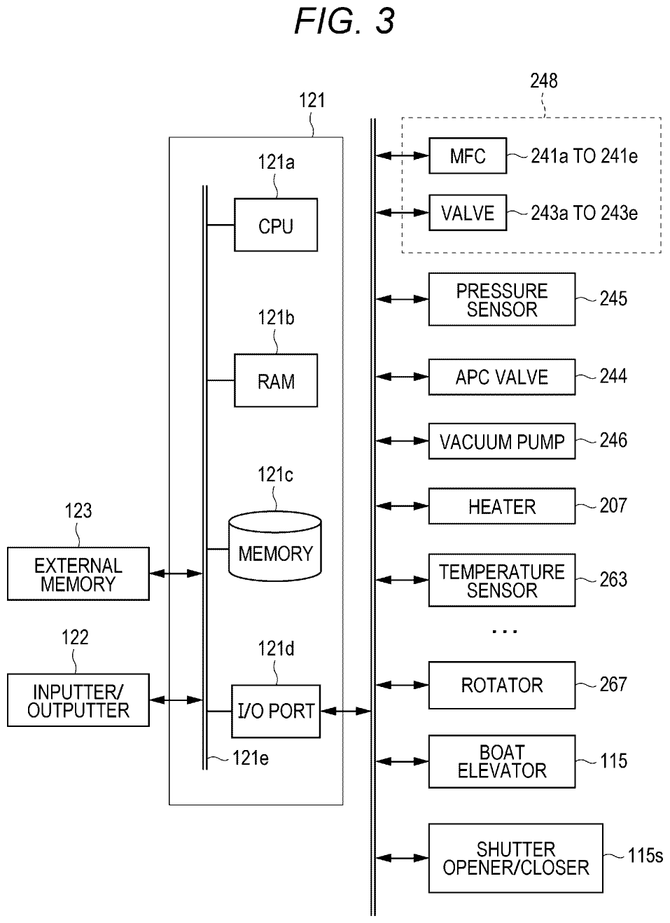

As illustrated in FIG. 3, the controller 121, which is a controller (controller), is configured as a computer including a central processing unit (CPU) 121a, random access memory (RAM) 121b, a memory 121c, and an I/O port 121d. The RAM 121b, the memory 121c, and the I/O port 121d are configured to be able to exchange data with the CPU 121a via an internal bus 121e. An inputter/outputter 122 configured as, for example, a touch panel and the like is connected to the controller 121. In addition, an external memory 123 can be connected to the controller 121. The substrate processing apparatus may be configured to include one controller or may be configured to include a plurality of controllers. That is, control for performing a processing sequence to be described later may be performed using one controller or a plurality of controllers. In addition, a plurality of controllers may be configured as a control system in which the controllers are mutually connected by a wired or wireless communication network, and control for performing the processing sequence to be described later may be performed by the entire control system. In a case where the term controller is used in the present specification, this might include a case where a plurality of controllers is included and a case where a control system composed of a plurality of controllers is included in addition to a case where one controller is included.

The memory 121c includes, for example, a flash memory, a hard disk drive (HDD), a solid state drive (SSD) and the like. In the memory 121c, a control program that controls operation of a substrate processing apparatus, a process recipe in which procedures, conditions, and the like of substrate processing described later are described, and the like are readably recorded and stored. The process recipe is a combination formed such that the controller 121 causes the substrate processing apparatus to execute each procedure in substrate processing described later to obtain a predetermined result, and functions as a program. Hereinafter, the process recipe, the control program and the like are collectively and simply referred to as a program. In addition, the process recipe is simply referred to as a recipe. In a case where the term program is used in the present specification, this might include the recipe alone, the control program alone, or both of them. The RAM 121b is configured as a memory area (work area) in which programs, data and the like read by the CPU 121a are temporarily stored.

The I/O port 121d is connected to the MFCs 241a to 241e, the valves 243a to 243e, the pressure sensor 245, the APC valve 244, the vacuum pump 246, the temperature sensor 263, the heater 207, the rotator 267, the boat elevator 115, the shutter opener/closer 115s and the like described above.

The CPU 121a is configured to be able to read the control program from the memory 121c and execute the control program, and read the recipe from the memory 121c in response to an input and the like of an operation command from the inputter/outputter 122. The CPU 121a is configured to be able to control, in accordance with a content of the read recipe, a flow rate regulating operation of various substances (various gases) by the MFCs 241a to 241e, an opening/closing operation of the valves 243a to 243e, a pressure regulating operation by the APC valve 244 based on an opening/closing operation of the APC valve 244 and the pressure sensor 245, start and stop of the vacuum pump 246, a temperature regulating operation of the heater 207 based on the temperature sensor 263, rotation and rotating speed regulating operation of the boat 217 by the rotator 267, a lifting operation of the boat 217 by the boat elevator 115, an opening/closing operation of the shutter 219s by the shutter opener/closer 115s and the like.

The controller 121 can be configured by installing the above-described program recorded and stored in the external memory 123 into the computer. Examples of the external memory 123 include a magnetic disk such as an HDD, an optical disk such as a CD, a magneto-optical disk such as an MO, and a semiconductor memory such as a USB memory or an SSD. The memory 121c and the external memory 123 are each configured as a computer-readable recording medium storing the program. Hereinafter, these are also collectively and simply referred to as a recording medium. In a case where the term recording medium is used in the present specification, this might include a case where only the memory 121c alone is included, a case where only the external memory 123 alone is included, or a case where both of them are included. The program may be provided to the computer by using a communicator such as the Internet and a dedicated line without using the external memory 123.

### (2) Substrate Processing Step

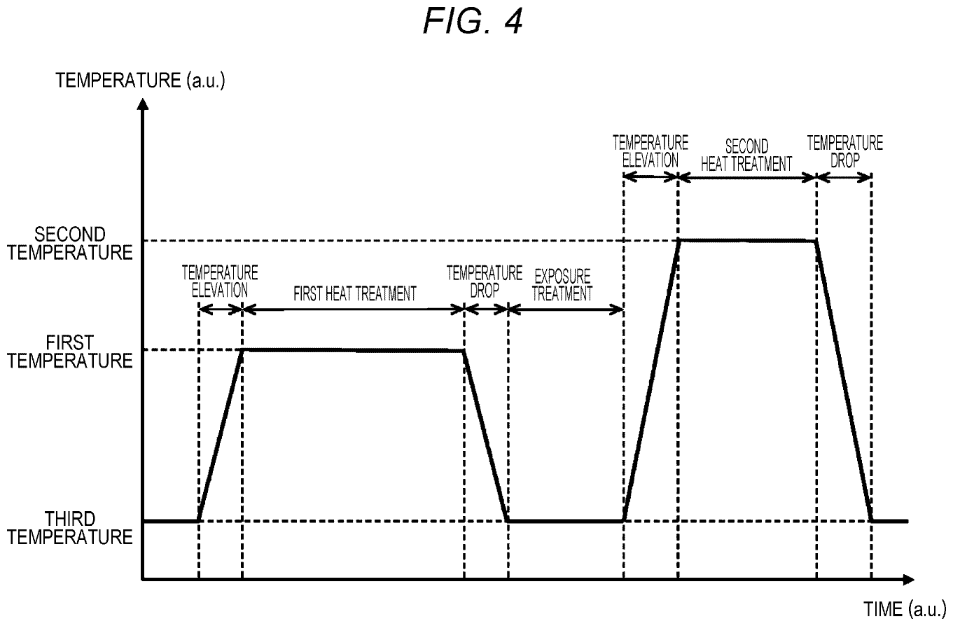

As one step of the step of manufacturing a semiconductor device using the substrate processing apparatus described above, a method of processing a substrate including a film containing a group 14 element, that is, a sequence example of processing the film containing a group 14 element formed on the wafer 200 serving as a substrate will be described mainly with reference to FIG. 4. In the following description, an operation of each unit included in the substrate processing apparatus is controlled by the controller 121.

As illustrated in FIG. 4, a processing sequence in the present aspect performs:
(a) a step (first heat treatment) of heat-treating the wafer 200 including a film containing a group 14 element at a first temperature,
(b) a step (second heat treatment) of heat-treating the wafer 200 at a second temperature higher than the first temperature, and
(c) a step (exposure treatment) of exposing the wafer 200 to a treatment agent containing at least one of oxygen (O) and hydrogen (H) after performing (a) and before performing (b).

In addition, as illustrated in FIG. 4, in the processing sequence in the present aspect, (c) is performed at a third temperature lower than the first temperature.

In the present specification, the above-described processing sequence may be expressed as described later for convenience. A similar expression will be used in the following description of modified examples, other aspects, and the like.

First heat treatment (first temperature)→exposure treatment (third temperature)→second heat treatment (second temperature)

The term “wafer” used in the present specification might mean the wafer itself, or a stack of the wafer and a predetermined layer or film formed on a surface thereof. The term “surface of the wafer” used in the present specification might mean the surface of the wafer itself or a surface of a predetermined layer and the like formed on the wafer. The phrase “forming a predetermined layer on the wafer” in the present specification might mean that a predetermined layer is directly formed on the surface of the wafer itself or that a predetermined layer is formed on the layer and the like formed on the wafer. In a case where the term “substrate” is used in the present specification, this is a synonym of the term “wafer”.

The terms “treatment agent” and “substance” used in the present specification include at least either a gaseous substance or a liquid substance. The liquid substance includes a mist substance. That is, the treatment agent or the substance may include a gaseous substance, a liquid substance such as a mist substance, or both of them.

### (Wafer Charge and Boat Load)

When a plurality of wafers 200 is loaded on the boat 217 (wafer charge), the shutter opener/closer 115s moves the shutter 219s, and the lower end opening of the manifold 209 is opened (shutter open). Thereafter, as illustrated in FIG. 1, the boat 217 that supports the plurality of wafers 200 is raised by the boat elevator 115 and is loaded into the process chamber 201 (boat load). In this state, the lower end of the manifold 209 is sealed with the seal cap 219 via the O-ring 220b. In this manner, the wafers 200 are prepared (provided) in the process chamber 201.

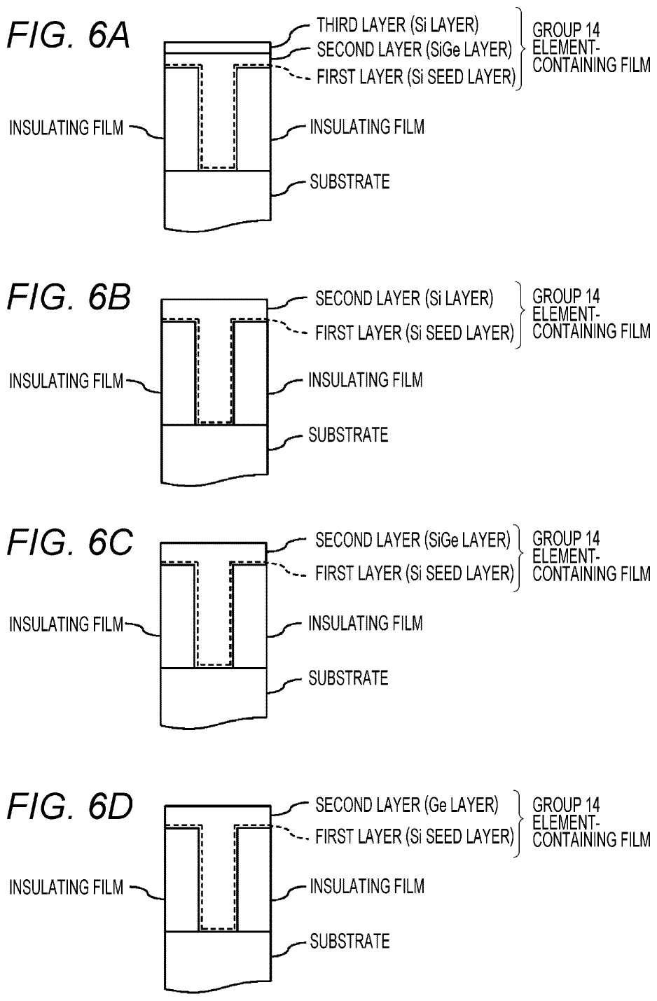

As the wafer 200, for example, a Si substrate composed of single crystal silicon (Si) or a substrate having a single crystal Si film formed on a surface thereof can be used. As illustrated in FIG. 6A, for example, an insulating film such as a silicon oxide film (SiO film) is formed on the surface of the wafer 200, and this may form a concave portion such as a trench and a hole. Both the bottom and the side wall of the concave portion may be composed of an insulating film, or both the bottom and the side wall of the concave portion may be composed of single crystal Si. In addition, the surface of the wafer 200 may be configured as a flat surface having no concave portion.

On the surface of the wafer 200, as a film containing a group 14 element, a film containing at least one of silicon (Si) and germanium (Ge) is formed in advance so as to fill the above-described concave portion, for example. In the present specification, this film is also referred to as a treatment target film. As an example, as illustrated in FIG. 6A, the treatment target film in the present aspect includes a multilayer structure of a first layer (Si seed layer) containing Si formed to cover the inner and outer surfaces of the concave portion formed on the wafer 200, a second layer (SiGe layer) containing Si and Ge formed on the first layer, and a third layer (Si layer) containing Si formed on the second layer. That is, the treatment target film in the present aspect contains both Si and Ge. Here, as an example, an aspect in which the inside of the concave portion is completely filled is indicated, but it is not limited thereto. For example, a film including at least one of the first layer, the second layer, and the third layer may be formed on the surface of the concave portion (the bottom surface and the side surface of the concave portion) without completely filling the inside of the concave portion. In other words, a film including at least one of the first layer, the second layer, and the third layer is formed on the bottom surface and the side surface of the concave portion. As described above, since the film containing the group 14 element formed on the surface of the concave portion is thinner than the case where the concave portion is completely filled, there may be a problem that it is difficult to increase the grain size of the film containing the group 14 element. In particular, when the film containing the group 14 element is uniformly formed on the surface of the concave portion, it is particularly difficult to increase the grain size.

The Si seed layer serving as the first layer can be formed, for example, by alternately supplying a halosilane-based gas and a first silane-based gas to the wafer 200 a predetermined number of times (n times, n is an integer of 1 or 2 or more).

As the halosilane-based gas, for example, a fluorosilane-based gas such as a difluorosilane (SiH₂F₂) gas; a chlorosilane-based gas such as a monochlorosilane (SiH₃Cl) gas, a dichlorosilane (SiH₂Cl₂) gas, a trichlorosilane (SiHCl₃) gas, a hexachlorodisilane (Si₂Cl₆) gas, and an octachlorotrisilane (Si₃Cl₈) gas; a bromosilane-based gas such as a dibromosilane (SiH₂Br₂) gas; and a iodosilane-based gas such as a diiodosilane (SiH₂I₂) gas can be used. One or more of these can be used as the halosilane-based gas.

As the first silane-based gas, for example, a silicon hydride gas such as a monosilane (SiH₄) gas, a disilane (Si₂H₆) gas, a trisilane (Si₃H₈) gas, a tetrasilane (Si₄H₁₀) gas, a pentasilane (Si₅H₁₂) gas, and a hexasilane (Si₆H₁₄) gas; an organic silane-based gas such as a monomethylsilane (SiH₃CH₃) gas, a dimethylsilane (SiH₂(CH₃)₂) gas, and a monoethylsilane (SiH₃C₂H₅) gas; and an aminosilane-based gas such as trisdimethylaminosilane (Si[N(CH₃)₂]₃H) gas and a bisdiethylaminosilane (Si[N(C₂H₅)₂]₂H₂) gas can be used. One or more of these can be used as the first silane-based gas.

The treatment temperature at the time of forming the Si seed layer can be, for example, 350 to 450° C., and the treatment pressure can be, for example, 400 to 1000 Pa. The supply flow rates of the halosilane-based gas and the first silane-based gas can be, for example, 10 to 1000 sccm.

In addition, the SiGe layer serving as the second layer can be formed, for example, by supplying a second silane-based gas and a germane-based gas to the wafer 200.

As the second silane-based gas, for example, the above-described silicon hydride gas, organic silane-based gas, and aminosilane-based gas exemplified as the first silane-based gas can be used. One or more of these can be used as the second silane-based gas. As the germane-based gas, for example, a germanium hydride gas such as a monogermane (GeH₄) gas, an organic germane-based gas, or an aminogermane-based gas can be used. One or more of these can be used as the germane-based gas.

The treatment temperature at the time of forming the SiGe layer can be, for example, 300 to 450° C., and the treatment pressure can be, for example, 1 to 1000 Pa. The supply flow rates of the second silane-based gas and the germane-based gas can be, for example, 10 to 2000 sccm.

In addition, the Si layer serving as the third layer can be formed, for example, by supplying the second silane-based gas to the wafer 200.

As the second silane-based gas, for example, the above-described silicon hydride gas, organic silane-based gas, and aminosilane-based gas exemplified as the first silane-based gas can be used. One or more of these can be used as the second silane-based gas.

The treatment temperature at the time of forming the Si layer can be, for example, 400 to 650° C., and the treatment pressure can be, for example, 30 to 200 Pa. The supply flow rate of the second silane-based gas can be, for example, 10 to 2000 sccm.

### (Temperature Elevation)

The output of the heater 207 is adjusted so that the temperature in the process chamber 201, that is, the temperature of the wafer 200 becomes a predetermined temperature (first temperature). At this time, the degree of energization to the heater 207 is feedback-controlled based on temperature information detected by the temperature sensor 263 such that the inside of the process chamber 201 has a desired temperature distribution. In addition, vacuum exhaust (depressurization exhaust) is performed by the vacuum pump 246 such that the inside of the process chamber 201, namely, the space where the wafer 200 exists has a predetermined pressure (first pressure). At that time, the pressure in the process chamber 201 is measured by the pressure sensor 245, and the APC valve 244 is feedback-controlled on the basis of information of the measured pressure. In addition, the rotator 267 starts rotating the wafer 200. Both the exhaust in the process chamber 201 and the heating and rotation of the wafer 200 are continuously performed at least until the processing on the wafer 200 ends.

### (First Heat Treatment)

After the temperature in the process chamber 201, that is, the temperature of the wafer 200 becomes the first temperature and is stabilized, the wafer 200, that is, the treatment target film of the wafer 200 is heat-treated at the first temperature (first heat treatment). This step is preferably performed in an inert gas atmosphere. That is, when performing this step, it is preferable that the valves 243c to 243e be opened to supply the inert gas into the process chamber 201 via the nozzles 249a to 249c to purge the inside of the process chamber 201.

By heat-treating the wafer 200 under the processing conditions described later, a first crystal nucleus containing the group 14 element (Si or Ge) can be generated in a predetermined region in the treatment target film. In addition, each first crystal nucleus generated in the treatment target film can be grown to have a desired size. In order to efficiently progress these reactions, this step is preferably performed at a temperature at which the group 14 element contained in the treatment target film is crystallized or a temperature close thereto (for example, a temperature within ±20° C. with respect to the temperature at which the group 14 element is crystallized).

The processing conditions in the first heat treatment are exemplified as follows:
Treatment temperature (first temperature): 330 to 600° C.
Treatment pressure (first pressure): atmospheric pressure (about 101325 Pa) or fine depressurization (10000 to 90000 Pa)
Treatment time: 5 to 30 hours
Inert gas supply flow rate (per gas supply pipe): 0 to 10000 sccm.

In the present specification, the expression of a numerical range such as “330 to 600° C.” means that a lower limit value and an upper limit value are included in the range. Thus, for example, “330 to 600° C.” means “greater than or equal to 300° C. and less than or equal to 600° C.”. The same applies to other numerical ranges. In addition, in the present specification, the treatment temperature means the temperature of the wafer 200 or the temperature in the process chamber 201, and the treatment pressure means the pressure in the process chamber 201. In addition, the treatment time means a time in which the treatment is continued. In addition, when 0 sccm is included in the substance (gas) supply flow rate, 0 sccm means a case where the substance is not supplied. The same applies to the following description.

As the inert gas, a nitrogen (N₂) gas or a rare gas such as an argon (Ar) gas, a helium (He) gas, a neon (Ne) gas, and a xenon (Xe) gas can be used. One or more of these can be used as the inert gas. The same applies to each step described later.

### (Temperature Drop)

After the first heat treatment is completed, the output of the heater 207 is adjusted so that the temperature in the process chamber 201, that is, the temperature of the wafer 200 is changed from the above-described first temperature to a predetermined third temperature lower than the first temperature. In addition, vacuum exhaust (depressurization exhaust) is performed by the vacuum pump 246 such that the inside of the process chamber 201 has a predetermined pressure (third pressure). When performing this step, it is preferable that the valves 243c to 243e be opened to supply the inert gas into the process chamber 201 via the nozzles 249a to 249c to purge the inside of the process chamber 201.

### (Exposure Treatment)

After the temperature in the process chamber 201, that is, the temperature of the wafer 200 becomes the third temperature and is stabilized, the wafer 200, that is, the treatment target film of the wafer 200 after the first heat treatment is exposed to a treatment agent containing at least one of O and H. Here, a case where the exposure treatment is performed by supplying the treatment agent to the wafer 200 in the process chamber 201 will be described. In addition, a case where the treatment agent contains both a molecular substance containing O and H and a molecular substance containing O will be described.

Specifically, the valves 243a and 243b are opened to flow the substance containing O and H and the substance containing O into the gas supply pipes 232a and 232b, respectively. The flow rates of these substances are regulated by the MFCs 241a and 241b, respectively, and the substances are supplied into the process chamber 201 through the nozzles 249a and 249b, respectively, and exhausted through the exhaust port 231a. At this time, the wafer 200, that is, the treatment target film of the wafer 200 after the first heat treatment is exposed to the treatment agent, that is, the substance containing O and H and the substance containing O (exposure treatment). At that time, the valves 243c to 243e may be opened to supply the inert gas into the process chamber 201 via the nozzles 249a to 249c, respectively, to dilute the treatment agent. For example, the wafer 200 may be exposed to the treatment agent diluted with an inert gas to a concentration (volume ratio) of 10% or more and 25% or less.

The processing conditions in the exposure treatment are exemplified as follows:
Treatment temperature (third temperature): room temperature to 100° C., preferably room temperature (25° C.)
Treatment pressure (third pressure): atmospheric pressure (about 101325 Pa) or fine depressurization (10000 to 90000 Pa)
Treatment time: 0.5 to 2 hours
Supply flow rate of treatment agent containing O and H: 1 to 2000 sccm
Supply flow rate of treatment agent containing O: 1 to 2000 sccm
Inert gas supply flow rate (per gas supply pipe): 0 to 10000 sccm.

As the molecular substance containing O and H (treatment agent), for example, water vapor (H₂O gas), a hydrogen peroxide (H₂O₂) gas, a hydrogen (H₂) gas+an oxygen (O₂) gas, or a deuterium (D₂) gas+oxygen (O₂) gas can be used. One or more of these can be used as the molecular substance containing O and H. Description of two gases such as “H₂ gas+O₂ gas” in the present specification means a mixed gas of a H₂ gas and an O₂ gas. In a case of supplying a mixed gas, two gases may be mixed (premixed) in a supply pipe and then supplied into the process chamber 201, or the two gases may be separately supplied into the process chamber 201 from different supply pipes and mixed (post-mixed) in the process chamber 201.

In addition, as the molecular substance containing O (treatment agent), for example, an oxygen (O₂) gas, an ozone (O₃) gas, a nitrous oxide (N₂O) gas, a nitrogen dioxide (NO₂) gas, an oxygen radical (O₂*, O*), and atomic oxygen (O) can be used. One or more of these can be used as the molecular substance containing O.

As the treatment agent, the molecular substance containing O and H can be used alone, or the molecular substance containing O can be used alone. In addition, as the treatment agent, both the molecular substance containing O and H and the molecular substance containing O can also be used. When both the molecular substance containing O and H and the molecular substance containing O are used, the molecular substance containing O and H and the molecular substance containing O are preferably different substances.

After the predetermined treatment time ends, the valves 243a and 243b are closed, and the supply of the treatment agent into the process chamber 201 is stopped. Then, the inside of the process chamber 201 is vacuum-exhausted to remove the gaseous substance and the like remaining in the process chamber 201 from the inside of the process chamber 201. At this time, the valves 243c to 243e are opened to supply the inert gas into the process chamber 201 via the nozzles 249a to 249c. The inert gas supplied from the nozzles 249a to 249c acts as a purge gas, and accordingly, the inside of the process chamber 201 is purged (purge). At this time, in order to suppress the treatment agent from remaining in the process chamber 201, it is preferable to perform cycle purge in which vacuum exhaust and the above-described purge in the process chamber 201 are alternately performed a plurality of times.

### (Temperature Elevation)

After the exposure treatment is completed, the output of the heater 207 is adjusted so that the temperature in the process chamber 201, that is, the temperature of the wafer 200 is changed from the above-described third temperature to a predetermined second temperature higher than the third temperature and further higher than the above-described first temperature, which is a temperature at which the first heat treatment was performed. In addition, vacuum exhaust (depressurization exhaust) is performed by the vacuum pump 246 such that the inside of the process chamber 201 has a predetermined pressure (second pressure). When performing this step, it is preferable that the valves 243c to 243e be opened to supply the inert gas into the process chamber 201 via the nozzles 249a to 249c to purge the inside of the process chamber 201.

### (Second Heat Treatment)

After the temperature in the process chamber 201, that is, the temperature of the wafer 200 becomes the second temperature and is stabilized, the wafer 200, that is, the treatment target film of the wafer 200 after the exposure treatment is heat-treated again at the second temperature higher than the first temperature (second heat treatment). This step is preferably performed in an inert gas atmosphere. That is, when performing this step, it is preferable that the valves 243c to 243e be opened to supply the inert gas into the process chamber 201 via the nozzles 249a to 249c to purge the inside of the process chamber 201.

By heat-treating the wafer 200 under the processing conditions described later, a second crystal nucleus containing the group 14 element (Si or Ge) can be generated in a region in the treatment target film where the first crystal nucleus is not generated. In addition, it is possible to grow each of the first crystal nucleus generated in the treatment target film by performing the first heat treatment and the second crystal nucleus generated in the treatment target film by performing this step so as to have a desired size. By performing this step at the second temperature higher than the treatment temperature (first temperature) at the first heat treatment temperature, these reactions can be allowed to progress.

The processing conditions in the second heat treatment are exemplified as follows:
Treatment temperature (second temperature): 380 to 720° C. (temperature higher than first temperature)
Treatment pressure (second pressure): atmospheric pressure (about 101325 Pa) or fine depressurization (10000 to 90000 Pa)
Treatment time: 3 to 15 hours
Inert gas supply flow rate (per gas supply pipe): 0 to 10000 sccm.

### (Temperature Drop)

After the second heat treatment is completed, the output of the heater 207 is adjusted so that the temperature in the process chamber 201, that is, the temperature of the wafer 200 is changed from the above-described third temperature to a predetermined temperature (unloadable temperature) lower than the third temperature. In addition, the inert gas serving as the purge gas is supplied from each of the nozzles 249a to 249c into the process chamber 201 and is discharged from the exhaust port 231a. As a result, the inside of the process chamber 201 is purged, and a gas, a reaction by-product, and the like remaining in the process chamber 201 are removed from the inside of the process chamber 201 (after-purge). Thereafter, the atmosphere in the process chamber 201 is replaced with the inert gas (inert gas replacement), so that the pressure in the process chamber 201 is restored to a normal pressure (atmospheric pressure restoration).

### (Boat Unload and Wafer Discharge)

Thereafter, the boat elevator 115 lowers the seal cap 219, and the lower end of the manifold 209 is opened. Then, the processed wafer 200 is unloaded from the lower end of the manifold 209 to the outside of the reaction tube 203 in a state of being supported by the boat 217 (boat unload). After the boat unload, the shutter 219s is moved, and the lower end opening of the manifold 209 is sealed with the shutter 219s via the O-ring 220c (shutter close). After being unloaded to the outside of the reaction tube 203, the processed wafer 200 is taken out from the boat 217 (wafer discharge).

### (3) Effects of the Present Embodiment

According to the present embodiment, one or a plurality of effects described later can be obtained.

(a) By sequentially performing the above-described first heat treatment, exposure treatment, and second heat treatment on the wafer 200 including the film containing the group 14 element, the diameter (grain size) of the crystal grains constituting the film containing the group 14 element can be increased. That is, by performing the first heat treatment, the first crystal nucleus containing the group 14 element can be generated and grown in the film containing the group 14 element. In addition, by performing the exposure treatment after the first heat treatment and then performing the second heat treatment, the second crystal nucleus containing the group 14 element can be generated in the region where the first crystal nucleus is not generated in the film, and each of the first crystal nucleus and the second crystal nucleus can be grown in the film. This makes it possible to increase the grain size of the crystal grains constituting the film containing the group 14 element. This makes it possible to improve the characteristics of the film containing the group 14 element.

(b) By performing the exposure treatment at the third temperature lower than the first temperature, oxidation of the film containing the group 14 element can be suppressed. This makes it possible to prevent deterioration of the characteristics of the film containing the group 14 element.

(c) By setting the third temperature to room temperature, that is, by performing the exposure treatment at room temperature, oxidation of the film containing the group 14 element can be more reliably suppressed. This makes it possible to more reliably prevent deterioration of the characteristics of the film containing the group 14 element.

(d) When the treatment agent containing at least one of O and H contains the molecular substance containing O and H and the molecular substance containing O, the above-mentioned effects can be reliably obtained.

(e) By performing the exposure treatment at the atmospheric pressure, it is possible to suppress aggregation of the crystal grains constituting the film containing the group 14 element and increase the grain size of the crystal grains.

(f) By performing the exposure treatment in the finely depressurized atmosphere, it is possible to more reliably suppress aggregation of the crystal grains constituting the film containing the group 14 element and further increase the grain size of the crystal grains.

(g) In the exposure treatment, by exposing the wafer 200 to the treatment agent diluted to a concentration of 10% or more and 25% or less, it is possible to more reliably suppress oxidation of the film containing the group 14 element while increasing the grain size. This makes it possible to more reliably prevent deterioration of the characteristics of the film containing the group 14 element. In the case of less than 10%, oxidation of the film containing the group 14 element can be suppressed, but there is a possibility that the effect of increasing the grain size cannot be sufficiently obtained. In addition, when the concentration is higher than 25%, the film containing the group 14 element may be oxidized.

(h) By performing each of the first heat treatment and the second heat treatment in an inert gas atmosphere, oxidation of the film containing the group 14 element can be more reliably suppressed. This makes it possible to more reliably prevent deterioration of the characteristics of the film containing the group 14 element.

(i) By performing the exposure treatment by supplying the treatment agent to the wafer 200 in the process chamber 201, it becomes easy to precisely and appropriately regulate various processing conditions (for example, the treatment temperature, the treatment pressure, the composition and concentration of the treatment agent, and the like) in the exposure treatment, and the above-described effects can be more reliably obtained.

(j) By performing the first heat treatment at a temperature close to the temperature at which the group 14 element contained in the treatment target film is crystallized, the above-described effects can be more reliably obtained.

(k) When the film containing the group 14 element contains at least one of Si and Ge as the group 14 element, the above-described reaction can be effectively caused.

(l) Even when the film containing the group 14 element is formed on the surface (the bottom surface and the side surface of the concave portion) of the concave portion of the wafer 200, a film having a large grain size can be uniformly formed on the surface of the concave portion. In particular, it is possible to form a film having a large grain size even when the film is uniformly formed on the surface of the concave portion without completely filling the inside of the concave portion.

(m) When the film containing the group 14 element is composed of two or more of the first layer (seed layer) and other layers, it is possible to more uniformly form a film having a large grain size.

(n) When the film containing the group 14 element contains Ge, the grain size can be further increased. In addition, the treatment temperature can be lowered. That is, a film having a large grain size can be obtained even at a low temperature.

(o) When the film containing the group 14 element has a three-layer structure of the first layer (Si seed layer) formed using the halosilane-based gas and the first silane-based gas, the second layer (SiGe layer) formed on the first layer using the second silane-based gas and the germane-based gas, and the third layer (Si layer) formed on the second layer using the second silane-based gas, the above-described reaction can be effectively caused.

(p) The above-described effects can be similarly obtained even in a case where a predetermined substance is optionally selected from the various treatment agents and various inert gases described above and used.

### Other Aspects of the Present Disclosure

The aspects of the present disclosure have been specifically described above. However, the present disclosure is not limited to the above aspects, and various changes can be made without departing from the gist thereof. Hereinafter, examples of other aspects of the present disclosure will be described. Unless otherwise specifically described, processing procedures and processing conditions in each step of another aspect described later can be made similar to the processing procedures and processing conditions in each step of the processing sequence described above.

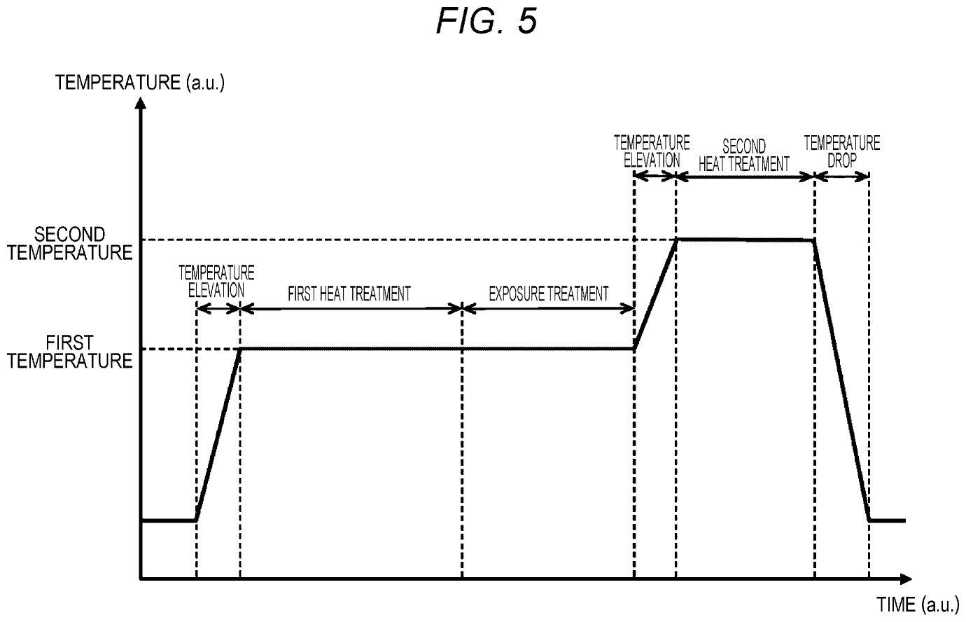

For example, as illustrated in FIG. 5, the exposure treatment may be performed at the first temperature. That is, the temperature at which the exposure treatment is performed may not be a temperature lower than the first temperature. Even in this case, effects similar to those in the above-described aspects can be obtained.

In addition, for example, in the exposure treatment, as the treatment agent, the molecular substance containing O and H may be used alone, or the molecular substance containing O may be used alone. Even in these cases, effects similar to those in the above-described aspects can be obtained.

In addition, for example, after the first heat treatment is performed, the atmosphere may be introduced into the process chamber, and the exposure treatment with respect to the substrate may be performed in the atmospheric atmosphere. In addition, for example, after the first heat treatment is performed, the substrate may be unloaded from the process chamber, and the exposure treatment with respect to the substrate may be performed in the atmospheric atmosphere. Even in these cases, effects similar to those in the above-described aspects can be obtained. When the atmosphere is introduced into the process chamber, it is preferable that the inside of the process chamber is cycle-purged and the atmosphere is reliably discharged from the process chamber after the exposure treatment is completed and before the second heat treatment is performed.

In addition, for example, as illustrated in FIG. 6B, the film containing the group 14 element may have a two-layer structure of the first layer (Si seed layer) formed using the halosilane-based gas and the first silane-based gas, and the second layer (Si layer) formed on the first layer using the second silane-based gas. Even in this case, effects similar to those in the above-described aspect can be obtained. In this case, the treatment temperature (first temperature) in the first heat treatment is preferably 500 to 600° C., and the treatment temperature (second temperature) in the second heat treatment is preferably 600 to 720° C.

In addition, for example, as illustrated in FIG. 6C, the film containing the group 14 element may have a two-layer structure of the first layer (Si seed layer) formed using the halosilane-based gas and the first silane-based gas, and the second layer (SiGe layer) formed on the first layer using the second silane-based gas and the germane-based gas. Even in this case, effects similar to those in the above-described aspect can be obtained. In this case, the treatment temperature (first temperature) in the first heat treatment is preferably 350 to 450° C., and the treatment temperature (second temperature) in the second heat treatment is preferably 450 to 600° C.

In addition, for example, as illustrated in FIG. 6D, the film containing the group 14 element may have a two-layer structure of the first layer (Si seed layer) formed using the halosilane-based gas and the first silane-based gas, and the second layer (Ge layer) formed on the first layer using the germane-based gas. Even in this case, effects similar to those in the above-described aspect can be obtained. In this case, the treatment temperature (first temperature) in the first heat treatment is preferably 330 to 380° C., and the treatment temperature (second temperature) in the second heat treatment is preferably 380 to 450° C.

In addition, for example, the processing sequence “the series of processing with respect to the substrate including the film containing the group 14 element (first heat treatment, exposure treatment, second heat treatment, and the like)” of the present disclosure may be performed continuously (in-situ) in the same process chamber (processing container). In addition, at least one of the series of processing and another processing may be performed in different process chambers (ex-situ). For example, at least two of the first heat treatment, the exposure treatment, and the second heat treatment are performed in different process chambers. Specifically, there are a case where the first heat treatment and the exposure treatment are performed in different process chambers, a case where the exposure treatment and the second heat treatment are performed in different process chambers, and a case where the first heat treatment and the second heat treatment are performed in different process chambers. In any case, effects similar to those in the above-described aspect can be obtained. When these pieces of processing are performed in-situ, it is possible to suppress contamination of the substrate, a change in surface state of the substrate, or the like, which may occur due to unloading of the substrate to the outside of the process chamber or loading from the outside of the process between the pieces of processing. In addition, when these are performed in-situ, the duration of transition between the pieces of processing can be shortened. On the other hand, when at least one of these pieces of processing is performed ex-situ, the pieces of processing can be performed in parallel in different process chambers, and productivity can be increased accordingly. In addition, the processing of forming the film containing the group 14 element on the substrate and at least one or more of the series of processing described above may be performed in-situ or ex-situ. For example, the film forming processing and the first heat treatment may be performed in-situ, and the other pieces of processing may be performed ex-situ.

Preferably, a recipe used in each processing is individually prepared according to processing contents and is recorded and stored in the memory 121c via an electric communication line or the external memory 123. Then, when each processing is started, the CPU 121a preferably appropriately selects an appropriate recipe from among the plurality of recipes recorded and stored in the memory 121c according to the processing contents. As a result, it is possible to form films having various film types, composition ratios, film qualities, and film thicknesses with good reproducibility by using one substrate processing apparatus. It is possible to reduce a burden on an operator, and to quickly start each processing while avoiding an operation error.

The recipe described above is not limited to a newly created recipe, but may be prepared by, for example, changing the existing recipe already installed in the substrate processing apparatus. In case of changing the recipe, the changed recipe may be installed in the substrate processing apparatus via an electric communication line or a recording medium in which the recipe is recorded. In addition, the existing recipe already installed in the substrate processing apparatus may be directly changed by operating the inputter/outputter 122 included in the existing substrate processing apparatus.

In the above-described aspects, an example has been described in which the film is formed using a batch-type substrate processing apparatus that processes a plurality of substrates at a time. The present disclosure is not limited to the aspects described above, and can be appropriately applied to a case of forming the film using a single wafer type substrate processing apparatus that processes one or more substrates at a time, for example. In addition, in the above-described aspects, an example has been described in which the film is formed by using a substrate processing apparatus including a hot wall-type processing furnace. The present disclosure is not limited to the above-described aspects, and is suitably applicable to a case where the film is formed by using a substrate processing apparatus including a cold wall-type processing furnace.

Even in cases where such substrate processing apparatuses are used, each piece of processing can be performed in accordance with processing procedures and processing conditions similar to those in the above-described aspects and modified examples, so that effects can be obtained similar to those in the above-described aspects and modified examples.

The above-described aspects and modified examples can be used in combination as appropriate. Processing procedures and processing conditions at this time can be similar to, for example, the processing procedures and processing conditions in the aspects and modified examples described above.

According to the present disclosure, it is possible to improve characteristics of a film containing a group 14 element formed on a substrate.

What is claimed is:

1. A substrate processing method comprising:
(a) heat-treating a substrate including a film containing a group 14 element at a first temperature;
(b) heat-treating the substrate at a second temperature higher than the first temperature; and
(c) exposing the substrate to a treatment agent containing at least one of O and H after performing (a) and before performing (b).

2. The method according to claim 1, wherein (c) is performed at a third temperature lower than the first temperature.

3. The method according to claim 2, wherein the third temperature is room temperature.

4. The method according to claim 1, wherein the treatment agent includes a substance containing O and H.

5. The method according to claim 1, wherein the treatment agent includes a substance containing O.

6. The method according to claim 1, wherein the treatment agent includes a substance containing O and H and a substance containing O.

7. The method according to claim 1, wherein (c) is performed at an atmospheric pressure.

8. The method according to claim 1, wherein (c) is performed in a finely depressurized atmosphere.

9. The method according to claim 1, wherein in (c), the substrate is exposed to the treatment agent diluted to a concentration of 10% or more and 25% or less.

10. The method according to claim 1, wherein each of (a) and (b) is performed in an inert gas atmosphere.

11. The method according to claim 1, wherein (c) is performed in an atmospheric atmosphere.

12. The method according to claim 1, wherein
in (a), a first crystal nucleus containing the group 14 element is generated and grown in the film, and
in (b), a second crystal nucleus containing the group 14 element is generated in a region where the first crystal nucleus is not generated in the film, and each of the first crystal nucleus and the second crystal nucleus is grown in the film.

13. The method according to claim 12, wherein (a) is performed at a temperature close to a temperature at which the group 14 element contained in the film is crystallized.

14. The method according to claim 1, wherein
the film includes
a first layer that contains Si and is formed using a halosilane-based gas and a first silane-based gas,
a second layer that contains Si and Ge and is formed on the first layer using a second silane-based gas and a germane-based gas, and
a third layer that contains Si and is formed on the second layer using the second silane-based gas.

15. The method according to claim 1, wherein
the film includes
a first layer that contains Si and is formed using a halosilane-based gas and a first silane-based gas, and
a second layer that contains Si and is formed on the first layer using a second silane-based gas.

16. The method according to claim 1, wherein
the film includes
a first layer that contains Si and is formed using a halosilane-based gas and a first silane-based gas, and
a second layer that contains Si and Ge and is formed on the first layer using a second silane-based gas and a germane-based gas.

17. The method according to claim 1, wherein
the film includes
a first layer that contains Si and is formed using a halosilane-based gas and a first silane-based gas, and
a second layer that contains Ge and is formed on the first layer using a germane-based gas.

18. A method of manufacturing a semiconductor device, comprising the steps of claim 1.

19. A non-transitory computer-readable recording medium recording a program for a computer to cause a substrate processing apparatus to execute:
(a) a procedure of heat-treating a substrate including a film containing a group 14 element at a first temperature;
(b) a procedure of heat-treating the substrate at a second temperature higher than the first temperature; and
(c) a procedure of exposing the substrate to a treatment agent containing at least one of O and H after performing (a) and before performing (b).

20. A substrate processing apparatus comprising:
a heater that heats a substrate;
a treatment agent supply system that supplies a treatment agent containing at least one of O and H to the substrate; and
a controller configured to be able to control the heater and the treatment agent supply system to perform
(a) processing of heat-treating the substrate including a film containing a group 14 element at a first temperature,
(b) processing of heat-treating the substrate at a second temperature higher than the first temperature, and
(c) processing of exposing the substrate to a treatment agent containing at least one of O and H after performing (a) and before performing (b).
